(19) United States
(12) Patent Application Publication
(10) Pub. No.: US 2026/0347597 A1
(43) Pub. Date: Nov. 5, 2026

(54) RESIN COMPOSITION AND METHOD FOR PRODUCING SAME

(71) Applicant: KANEKA CORPORATION, Osaka (JP)

(72) Inventors: Yoshio Furukawa, Osaka (JP); Aiko Katsura, Osaka (JP); Makoto Hasegawa, Osaka (JP)

(73) Assignee: KANEKA CORPORATION, Osaka (JP)

(21) Appl. No.: 19/699,886

(22) Filed: Jun. 5, 2026

Related U.S. Application Data
(63) Continuation of application No. PCT/JP2024/042451, filed on Dec. 2, 2024.

(30) Foreign Application Priority Data
Dec. 6, 2023 (JP) 2023-206494

(51) Int. Cl. C08L 33/12; C08F 120/14; C08J 5/18; G02B 1/14; G02B 5/30

(52) U.S. Cl. CPC C08L 33/12; C08F 120/14; C08J 5/18; G02B 1/14; C08J 2333/12; C08J 2433/12; C08L 2203/16; C08L 2205/025; C08L 2207/53; C08L 2312/00; G02B 5/3025

(57) ABSTRACT

A resin composition containing a methacrylic resin having a triad syndiotacticity of 55% or more and a weight average molecular weight (Mw) of 500,000 or more as measured by gel permeation chromatography (GPC), and acrylic crosslinked particles is provided. A method for producing the resin composition, a dope for producing a film containing the resin composition, a resin film containing the resin composition, and a polarizing plate and a display device using the resin film, are also provided.

### TECHNICAL FIELD

One or more embodiments of the present invention relate to a resin composition and a method for producing the same.

### BACKGROUND

Methacrylic resins are widely used in various fields because they have excellent transparency, weather resistance, processability, and the like. In particular, a resin film obtained by molding a methacrylic resin is also used in optical applications such as display devices because of its excellent optical properties.

As a method for producing the resin film, a melt extrusion method using a T-die, a solution casting method in which a dope obtained by dissolving a resin in a solvent is cast on the surface of a support and then the solvent is evaporated to form a film, and the like are known. Among them, the solution casting method is advantageous in that since physical stress applied to the resin film during film formation is small, orientation of the polymer is unlikely to occur, and the strength and optical properties of the obtained resin film are isotropic. In addition, according to the solution casting method, there is an advantage that thickness accuracy of the obtained resin film is extremely high.

When the resin film is produced by the solution casting method, a methacrylic resin with a high molecular weight is generally used as the methacrylic resin. Use of a methacrylic resin with a high molecular weight not only makes it suitable for the solution casting method but also makes it possible to obtain a resin film having good mechanical properties.

### PATENT DOCUMENTS

Patent Document 1: PCT International Publication No. WO 2019/167471

However, as a result of investigation by the present inventors, it has been found that such a high-molecular-weight methacrylic resin has room for improvement in terms of heat resistance and mechanical characteristics.

### SUMMARY

One or more embodiments of the present invention are to provide a resin composition including a methacrylic resin capable of producing a molded article excellent in the heat resistance and the mechanical characteristics while maintaining transparency, and a method for producing the same.

Specific means for addressing the above include the following embodiments.
<1> A resin composition including:
   a methacrylic resin having a triad syndiotacticity of 55% or more and a weight average molecular weight (Mw) as measured by gel permeation chromatography (GPC) of 500,000 or more, and acrylic crosslinked particles.
<2> The resin composition as described in <1>, in which a mass ratio of the methacrylic resin and the acrylic crosslinked particles is 99.9:0.1 to 65:35 inclusive.
<3> The resin composition as described in <1> or <2>, in which a proportion of a structural unit derived from methyl methacrylate is 99.5% by mass or more.
<4> The resin composition as described in <1> or <2>, in which the methacrylic resin has a ratio (Mw/Mn) of weight average molecular weight (Mw) to number average molecular weight (Mn) of 1.6 to 2.8 inclusive.
<5> The resin composition as described in any one of <1> to <4>, in which a proportion of terminal double bonds to structural units derived from methyl methacrylate is less than 0.02 mol %.
<6> The resin composition as described in any one of <1> to <5>, in which the methacrylic resin includes a terminal structure derived from a polymerization initiator and represented by the following formula (1):

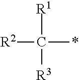

in the formula, R¹, R², and R³ each independently represent an alkyl group, a substituted alkyl group, an ester group, or an amide group, provided that at least one of R¹, R², or R³ represents an ester group or an amide group, two of R¹, R², or R³ may be bonded to each other to form an alicyclic structure, and * represents a bond to a structural unit derived from a monomer.
<7> The resin composition as described in any one of <1> to <6>, in which the acrylic crosslinked particles are core-shell elastomers having a core layer composed of a rubber-like polymer, and a shell layer composed of a glass-like polymer.
<8> A dope for use in production of a film by a solution casting method,
   in which the dope includes the resin composition as described in any one of <1> to <7> and a solvent,
   the solvent includes a first solvent having a hydrogen bond term δH in a Hansen solubility parameter of 1 to 12 inclusive and a second solvent having a hydrogen bond term δH of 14 to 24 inclusive.
<9> A resin film including the resin composition as described in any one of <1> to <7>.
<10> The resin film as described in <9>, having a glass transition temperature of 120 °C or higher.
<11> The resin film as described in <9> or <10>, in which a fold number in an MIT folding endurance test is 2,500 times or more.
<12> The resin film as described in any one of <9> to <11>, having an internal haze of 0.4% or less.
<13> The resin film as described in any one of <9> to <12>, having value b* of 0.3 or less.
<14> A method for producing the resin composition as described in any one of <1> to <7>,
   in which the method includes a production method of a methacrylic resin, including a polymerization step of polymerizing a monomer mixture having a methyl methacrylate content of 99.5% by mass or more in the presence of a polymerization initiator and a chain transfer agent, in the polymerization step, a polymerization temperature until 90% or more of the methacrylic resin to be obtained is produced is set to lower than 100 °C,
   an amount of the chain transfer agent used is 0.03 mol % or less with respect to a total amount of the monomer mixture, and
   a ratio of a molar amount of the chain transfer agent to a total molar amount of the polymerization initiator is 3.0 or less.
<15> The method for producing the resin composition as described in <14>, in which the polymerization initiator is a non-nitrile azo polymerization initiator in the production method of a methacrylic resin.
<16> The method for producing a resin composition as described in <14> or <15>, in which aqueous polymerization is performed in the polymerization step in the production method of a methacrylic resin.
<17> The resin film as described in any one of <9> to <13>, in which the resin film is an optical film.
<18> The resin film as described in any one of <9> to <13>, in which the resin film is a polarizer protective film.
<19> A polarizing plate including a laminate of a polarizer and the resin film as described in any one of <9> to <13>.
<20> A display device including the polarizing plate as described in <19>.

According to one or more embodiments of the present invention, it is possible to provide a resin composition capable of producing a molded article excellent in the heat resistance and the mechanical characteristics while maintaining transparency, a method for producing the same, and a resin film containing the resin composition.

### DETAILED DESCRIPTION

Hereinafter, one or more embodiments of the present invention will be described in detail. The symbol “-” representing a numerical range is used to include the lower limit and the upper limit of the range, unless otherwise specified.

### <Methacrylic Resin>

The methacrylic resin according to one or more embodiments may have a triad syndiotacticity (hereinafter, also referred to as “rr”) of 55% or more, 56% or more, or 57% or more. When the rr is 55% or more, glass transition temperature (Tg) of the methacrylic resin becomes high, and the heat resistance tends to be improved. The upper limit of the rr is not particularly limited, but may be 67% or less, 65% or less, or 63% or less, from the viewpoints of molding temperature, toughness, and secondary workability of a molded article.

The rr refers to a percentage that two successive chains (diad) possessed by a chain (triad) composed of three successive structural units are both racemo. Note that, in a chain (diad) of structural units in a polymer molecule, a diad having the same steric configuration is referred to as meso, and a diad having reversed steric configurations is referred to as racemo, the meso and the raceme being denoted by m and r, respectively.

As described in Examples below, the rr can be calculated using formula: (X/Y)×100, where X and Y are an area (X) of a region of 0.60 to 0.95 ppm and an area (Y) of a region of 0.60 to 1.25 ppm, respectively, provided that X and Y are measured from a ¹H-NMR spectrum measured in deuterated chloroform at 22 °C for 16 integrations, when tetramethylsilane (TMS) is assigned as 0 ppm.

The methacrylic resin according to one or more embodiments may have a Tg of 120 °C or higher, 122 °C or higher, or 124 °C or higher. The upper limit of the Tg is not particularly limited, but may be 135 °C or lower, or may be 130 °C or lower from the viewpoints of molding temperature and secondary workability of the molded article.

In the present specification, the Tg is a midpoint glass transition temperature determined from a DSC curve and is measured by the method described in the Examples described below.

The rr and Tg of a methacrylic resin can be controlled by adjusting a polymerization temperature when synthesizing the methacrylic resin. For example, lowering the polymerization temperature is preferable in increasing the rr of the methacrylic resin and increasing the Tg. The Tg can also be controlled by adjusting the molecular weight of the methacrylic resin.

The methacrylic resin according to one or more embodiments has a weight average molecular weight (Mw) of 500,000 or more. When the methacrylic resin has an Mw of 500,000 or more, the mechanical properties of a molded article obtained tend to be improved, and for example, a resin film excellent in folding endurance can be obtained. The methacrylic resin may have an Mw of 600,000 or more, 700,000 or more, or 800,000 or more. The upper limit of the Mw is not particularly limited, but may be 4 million or less, 3.5 million or less, 3 million or less, 2 million or less, or 1.5 million or less, from the viewpoint of moldability.

Further, the methacrylic resin according to one or more embodiments may have a dispersity (Mw/Mn), i.e., a ratio of the Mw to the number average molecular weight (Mn), of 1.6 to 2.8, 1.7 to 2.5, 1.7 to 2.4, or 1.7 to 2.3. When the dispersity (Mw/Mn) of the methacrylic resin is 1.6 or more, fluidity of the methacrylic resin is improved and the resin is easier to mold. When the dispersity (Mw/Mn) of the methacrylic resin is 2.8 or less, mechanical properties such as impact resistance, toughness, and folding endurance of the molded article obtained tend to be improved.

In the present specification, the Mw and the Mn are values in terms of standard polystyrene measured by gel permeation chromatography (GPC) and are measured by the method described in the Examples below.

Note that the Mw and the Mn of the methacrylic resin can be controlled by adjusting the types, amounts used, etc. of the polymerization initiator and the chain transfer agent in synthesizing the methacrylic resin.

In the methacrylic resin according to one or more embodiments, a proportion of a structural unit derived from methyl methacrylate may be 99.5% by mass or more and a proportion of a structural unit derived from a monomer other than methyl methacrylate may be 0.5% by mass or less. When the proportion of the structural unit derived from methyl methacrylate is 99.5% by mass or more, transparency of the resin film molded by the resin composition according to one or more embodiments, which is described later, can be improved. In addition, since the content of methyl methacrylate is high, amounts of impurities are small, which is also suitable from the viewpoint of recycling. Note that the structural unit derived from methyl methacrylate is represented by the following formula.

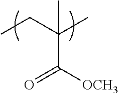

Examples of monomers other than methyl methacrylate include alkyl esters of acrylic acid such as methyl acrylate, ethyl acrylate, propyl acrylate, butyl acrylate, 2-ethylhexyl acrylate, etc.; aryl esters of acrylic acid, such as phenyl acrylate; cycloalkyl esters of acrylic acid, such as cyclohexyl acrylate, norbornenyl acrylate, etc.; alkyl esters of methacrylic acid other than ethyl methacrylate, propyl methacrylate, butyl methacrylate, etc.; aryl esters of methacrylic acid such as phenyl methacrylate; cycloalkyl esters of methacrylic acid such as cyclohexyl methacrylate, norbornenyl methacrylate, etc.; aromatic vinyl compounds such as styrene, α-methylstyrene, etc.; acrylamides; methacrylamides; acrylonitrile; methacrylonitrile; and the like.

In addition, the methacrylic resin according to one or more embodiments may have a 5% weight loss temperature of 300 °C or higher and has excellent thermal stability.

In general, when producing a resin with a large molecular weight, a technique of reducing an amount of a chain transfer agent and/or a polymerization initiator to be used are/is employed. However, when, for example, a thiol compound is used as the chain transfer agent, the proportion of growing radicals that are terminated by a hydrogen abstraction reaction from the chain transfer agent decreases, and a relatively large number of polymers having double bond terminals are likely to be produced by a disproportionation termination reaction between growing radicals. It is known that the terminal double bond is thermally decomposed at a lower temperature than the main chain of the methacrylic resin (For example, T. Kashiwagi, et al., Macromolecules, 1986, 19, pp. 2160-2168, or the like), which causes deterioration of the thermal stability of the resin. In this regard, in the methacrylic resin according to one or more embodiments, a ratio between an amount of chain transfer agent and an amount of polymerization initiator during the production is adjusted to an appropriate range, thereby reducing the proportion of terminal double bond. As a result, the methacrylic resin according to one or more embodiments has an Mw as high as 500,000 or more but can have a 5% weight loss temperature of 300 °C or higher.

The 5% weight loss temperature in the present specification is a temperature determined from a thermogravimetric curve and is measured by the method described in the Examples below.

In the methacrylic resin according to one or more embodiments, the proportion of terminal double bonds to structural units derived from methyl methacrylate may be less than 0.02 mol %, less than 0.010 mol %, or less than 0.006 mol %, from the viewpoint of adjusting the 5% weight loss temperature to 300 °C or higher.

The methacrylic resin according to one or more embodiments can be produced by a radical polymerization method as shown in the production method described later. The methacrylic resin produced by the radical polymerization method contains a terminal double bond generated by a disproportionation termination reaction during polymerization, a hydrogen abstraction reaction of a monomer by a polymerization initiator, or the like. Since the terminal double bond affects the thermal stability of the resin, a proportion thereof may be small. The proportion of terminal double bonds is controlled by the method described below, and if the ratio can be reduced to a range of less than 0.015 mol %, the thermal stability of the methacrylic resin tends to be significantly improved. Note that the lower limit of the terminal double bond proportion may be 0 mol % but may be 0.0005 mol %.

The proportion of terminal double bonds to the structural unit derived from methyl methacrylate can be determined by, as described in the Examples below, measuring a 1H-MJR spectrum in deuterated chloroform at 20 °C for an integration number of 8,192 times; measuring a total area (X) of peaks (5.47 ppm to 5.52 ppm and 6.21 ppm) derived from the terminal double bond portion of the methacrylic resin and an area (Y) of peaks (0.5 ppm to 1.25 ppm) derived from an α-methyl group of the methacrylic resin from the spectrum; and calculating the ratio using the formula: [(3×X)/(2×Y)]×100.

The proportion of terminal double bonds of the methacrylic resin can be controlled by adjusting amounts of the polymerization initiator and the chain transfer agent to be used in synthesizing the methacrylic resin, the polymerization temperature, the polymerization time, and the like. For example, it is preferable to reduce the amount of the polymerization initiator to be used, to increase the amount of the chain transfer agent to be used, to lower the polymerization temperature, and to increase the polymerization time in order to reduce the proportion of terminal double bonds.

The methacrylic resin according to one or more embodiments may include a terminal structure represented by the following formula (1), the structure being derived from a polymerization initiator.

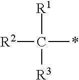

In the formula, R¹, R², and R³ each independently represent an alkyl group, a substituted alkyl group, an ester group, or an amide group; however, at least one of R¹, R², or R³ represents an ester group or an amide group; two of R¹, R², and R³ may be bonded to each other to form an alicyclic structure; and * represents a bond to a structural unit derived from the monomer.

Examples of the alkyl group include a linear or branched alkyl group having 1 to 6 carbon atoms. Examples of the substituent that the alkyl group may have include a hydroxy group, a carboxy group, an alkoxy group, a halogen atom, etc.

Examples of the ester group include a group represented by —COOR⁴. R⁴ represents an alkyl group having 1 to 6 carbon atoms, and may have a substituent such as a hydroxy group, a carboxy group, an alkoxy group, a halogen atom, or the like.

Examples of the amide group include a group represented by —C(O)NR⁵. R⁵ represents an alkyl group having 1 to 6 carbon atoms, a cycloalkyl group, or an alkenyl group having 2 to 6 carbon atoms and may have a substituent such as a hydroxy group, a carboxy group, an alkoxy group, a halogen atom, or the like.

The terminal structure represented by the above formula (1) can be introduced into the molecule of the methacrylic resin by using a non-nitrile azo polymerization initiator represented by the following formula (2) when synthesizing the methacrylic resin. In the formula, R¹, R², and R³ are as defined in the above formula (1). Use of such a non-nitrile azo polymerization initiator tends to improve the thermal stability of the methacrylic resin to be obtained as compared with a case of using a polymerization initiator other than the non-nitrile azo polymerization initiator (for example, a nitrile azo polymerization initiator). In addition, the non-nitrile azo polymerization initiator is preferable in that the toxicity of the initiator itself and/or decomposition products tend to be lower than that of the nitrile azo polymerization initiator.

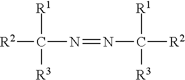

Examples of the non-nitrile azo polymerization initiator represented by the above formula (2) include dimethyl 2,2′-azobis(isobutyrate), 1,1′-azobis(cyclohexanecarboxylic acid methyl) ester, 2,2′-azobis[N-(2-propenyl)-2-methylpropionamide], 2,2′-azobis(N-butyl-2-methylpropionamide), 2,2′-azobis(N-cyclohexyl-2-methylpropionamide), 2,2′-azobis{2-methyl-N-[2-(1-hydroxyethyl)]propionamide}, 2,2′-azobis{2-methyl-N-[2-(1-hydroxybutyl)]propionamide}, etc. Among these, at least one selected from dimethyl 2,2′-azobis(isobutyrate) or 1,1′-azobis(cyclohexanecarboxylic acid methyl) ester is preferable from the viewpoints of half-life temperature, cost, and the like.

The methacrylic resin according to one or more embodiments may have a chain transfer agent residual proportion of 0.005% by mass or less, or substantially 0% by mass (that is, less than a detection limit). The chain transfer agent residual proportion is measured by the method described in the Examples below.

The methacrylic resin according to one or more embodiments is not only excellent in heat resistance and thermal stability but also expected to be suitable for reuse after disposal, that is, for recycling. As a method of recycling a methacrylic resin, for example, chemical recycling (method for recovering cracked oil as a cracked product by thermal cracking and reusing it as a chemical raw material or fuel) is known. In general, in order to improve the heat resistance and thermal stability of a methacrylic resin, a cyclic structure is introduced into the molecular structure of the methacrylic resin, or a monomer having a rigid structure is copolymerized. However, these structures are unpreferable because they are impurities in chemical recycling. In this regard, since the methacrylic resin according to one or more embodiments includes a large proportion of the structural unit derived from methyl methacrylate, and the monomer is expected to be recovered as cracked oil in a high yield, good chemical recyclability can be expected.

### <Production Method of Methacrylic Resin>

The production method of a methacrylic resin according to one or more embodiments includes a polymerization step of polymerizing a monomer mixture having a methyl methacrylate content of 99.5% by mass or more in the presence of a polymerization initiator and a chain transfer agent, and a polymerization temperature until 90% or more of the methacrylic resin to be obtained is produced is set to lower than 100 °C. Here, “until 90% or more of the methacrylic resin to be obtained is produced” means that “until at least a conversion ratio reaches 90%” when the polymerization reaction is performed up to a conversion ratio of 100%, and that “until at least the conversion ratio reaches 45%” when the polymerization reaction is ended at a conversion ratio of 50%, for example. After 90% or more of the methacrylic resin to be obtained is produced, the polymerization temperature may be raised to 100 °C or higher for the purpose of reducing monomer components remaining or deactivating the polymerization initiator remaining. As the production method of a methacrylic resin, a conventionally known polymerization method can be employed, and for example, a radical polymerization method such as a continuous bulk polymerization method, a solution polymerization method, an emulsion polymerization method, a non-emulsifier (soap-free) emulsion polymerization method, or a suspension polymerization method can be employed. Among them, from the viewpoints of a degree of freedom in structural design of the methacrylic resin, simplicity of polymerization, productivity, etc., a production method in which aqueous polymerization is performed is preferable, a suspension polymerization method and an emulsion polymerization method are more preferable, and a suspension polymerization method is further preferable.

### [Suspension Polymerization Method]

In the suspension polymerization method, the methacrylic resin is synthesized in an aqueous suspension in which water, a monomer mixture, a dispersant, a polymerization initiator, a chain transfer agent, and optionally other additives are mixed. The order of mixing components is not particularly limited. For example, an aqueous suspension may be prepared by mixing the components simultaneously. Alternatively, water, a polymerization initiator, and optional other additives may be mixed to prepare an aqueous solution, followed by addition of the monomer mixture and the chain transfer agent, followed by addition of a dispersant to prepare the aqueous suspension. A mass ratio of the methacrylic resin to be obtained to water (methacrylic resin/water) may be 1.0/0.6 to 1.0/3.0.

As the monomer mixture, a mixture having a methyl methacrylate content of 99.5% by mass or more is preferred.

Examples of the dispersant include sparingly water-soluble inorganic salts such as calcium triphosphate, magnesium pyrophosphate, hydroxyapatite, kaolin, etc.; water-soluble polymers such as polyvinyl alcohol, methyl cellulose, polyacrylamide and polyvinylpyrrolidone; and the like. When a sparingly water-soluble inorganic salt is used as the dispersant, it is effective to use an anionic surfactant such as sodium α-olefinsulfonate, sodium dodecylbenzenesulfonate, or the like, in combination. These dispersants may be added during the polymerization as necessary.

As the polymerization initiator, known polymerization initiators such as an azo polymerization initiator or a peroxide polymerization initiator can be used. Among known polymerization initiators, an azo polymerization initiator is preferable from the viewpoint of improving the thermal stability of the methacrylic resin to be obtained.

It is known that free radicals generated from a polymerization initiator cause, in addition to an addition reaction to a monomer, a hydrogen abstraction reaction in the presence of a substance that easily gives hydrogen. In this regard, the azo polymerization initiator generates only alkyl radicals and thus has lower hydrogen abstraction ability than peroxide polymerization initiators. Here, if the polymerization initiator has high hydrogen abstraction ability, for example, in a case where methyl methacrylate is used as the monomer, hydrogen is abstracted from the α-methyl group of the methyl methacrylate or the methyl group of the ester by free radicals generated from the polymerization initiator, and polymerization proceeds from radicals newly generated on the α-methyl group or methyl group of the ester. As a result, a polymer in which double bonds derived from the monomer structure remain at its terminal is easily formed. Therefore, when a polymerization initiator having a high hydrogen abstraction ability is used, the thermal stability of the methacrylic resin obtained tends to be insufficient. Thus, an azo polymerization initiator is more preferable than a peroxide polymerization initiator in order to obtain a methacrylic resin having high thermal stability.

The hydrogen abstraction ability of the polymerization initiator can be measured, for example, by a radical trapping method using an α-methylstyrene dimer (i.e., an α-methylstyrene dimer trapping method).

In addition, as a result of investigation by the present inventors using various polymerization initiators, it has been found that a methacrylic resin synthesized using a non-nitrile azo polymerization initiator has a thermally stable terminal structure introduced into the molecule as compared with a methacrylic resin synthesized using a polymerization initiator other than the non-nitrile azo polymerization initiator (for example, a nitrile azo polymerization initiator). Therefore, among the azo polymerization initiators, non-nitrile azo polymerization initiators are more preferable. Examples of the non-nitrile-based azo polymerization initiator include those represented by the above formula (2), and at least one selected from dimethyl 2,2′-azobis(isobutyrate) and 1,1′-azobis(cyclohexanecarboxylic acid methyl) ester is preferable from the viewpoints of half-life temperature, cost, and the like.

An amount of the polymerization initiator to be used may be 1 part by mass or less, 0.5 parts by mass or less, or 0.1 parts by mass or less with respect to 100 parts by mass of a total amount of the monomer mixture. The lower limit of the amount of the polymerization initiator to be used is not particularly limited but may be 0.001 parts by mass or more with respect to 100 parts by mass of the total amount of the monomer mixture from the viewpoint of the polymerization rate.

Examples of the chain transfer agent include primary alkyl mercaptan-based chain transfer agents such as n-butyl mercaptan, n-octyl mercaptan, n-hexadecyl mercaptan, n-dodecyl mercaptan, n-tetradecyl mercaptan, etc.; secondary alkyl mercaptan-based chain transfer agents such as s-butyl mercaptan, s-dodecyl mercaptan, etc.; tertiary alkyl mercaptan-based chain transfer agents such as t-dodecyl mercaptan, t-tetradecyl mercaptan, etc.; thioglycolic acid esters such as 2-ethylhexyl thioglycolate, ethylene glycol dithioglycolate, trimethylolpropane tris (thioglycolate), pentaerythritol tetrakis (thioglycolate), etc.; thiophenol, tetraethylthiuram disulfide, pentanephenylethane, acrolein, methacrolein, allyl alcohol, carbon tetrachloride, ethylene bromide, styrene oligomers (such as α-methylstyrene dimer, etc.), terpinolene; and the like. These chain transfer agents may be used alone or in combination of two or more types thereof.

Among these chain transfer agents, alkyl mercaptan-based chain transfer agents and thioglycolic acid esters are preferable, n-octyl mercaptan and 2-ethylhexyl thioglycolate are more preferable as the alkyl mercaptan-based chain transfer agent and the thioglycolic acid ester, respectively, from the viewpoints of handling property, stability, thermal stability of the methacrylic resin to be obtained, and the like.

An amount of the chain transfer agent used may be 0.03 mol % or less, or 0.025 mol % or less, based on a total amount of the monomer mixture. The lower limit of the amount of the chain transfer agent used is not particularly limited but may be 0.0015 mol % or more with respect to the total amount of the monomer mixture.

In order to obtain a methacrylic resin having a large Mw and a small proportion of terminal double bonds, a ratio of a total molar amount of the chain transfer agent to a total molar amount of the polymerization initiator may be 3.0 or less, 2.6 or less, or 2.0 or less. The lower limit of the ratio of a total molar amount of the chain transfer agent to a total molar amount of the polymerization initiator is not particularly limited but may be, for example, 0.1 or more.

A polymerization temperature during the synthesis of the methacrylic resin may be set to lower than 100 °C, 20 °C or higher and lower than 100 °C, 30 °C to 95 °C, 50 °C to 90 °C, or 60 °C to 85 °C, from the viewpoints of control of rr of the methacrylic resin obtained and productivity. After the main reaction is completed in the polymerization in the first stage, the temperature may be raised to a higher temperature than in the first stage to perform post-polymerization to reduce residual monomers.

Since polymerization is started with a small amount of polymerization initiator, the polymerization reaction may be performed by lowering an amount of dissolved oxygen. An amount of dissolved oxygen in the raw material for polymerization may be 10 ppm or less, 5 ppm or less, 4 ppm or less, or 2 ppm or less. By limiting the amount of dissolved oxygen to such a range, the polymerization reaction proceeds smoothly, and coloration of the molded article of the methacrylic resin tends to be suppressed. Examples of methods for removing oxygen dissolved in the raw material for polymerization include feeding an inert gas such as a nitrogen gas continuously into the reaction vessel before, during, and after temperature rise to a predetermined polymerization temperature. In order to also remove dissolved oxygen from raw materials to be added during polymerization, it is preferable to independently supply an inert gas to the raw materials.

When a polymerization inhibitor is contained in the monomer mixture, the polymerization inhibitor may be removed by distillation or alkali extraction, or by using an adsorbent such as alumina, silica gel, molecular sieves, activated carbon, an ion exchange resin, zeolite, or acidic clay, in order to allow the polymerization reaction to proceed smoothly.

A suspension containing the methacrylic resin obtained by the suspension polymerization may be subjected to a washing operation such as acid washing, water washing, or alkali washing in order to remove the dispersant. The number of times of performing these washing operations may be selected from an optimum number of times in consideration of the working efficiency and the removal efficiency of the dispersant and may be once or a plurality of times.

As a method of separating the methacrylic resin from the suspension containing the methacrylic resin, a conventionally known dehydration method can be employed. Examples of the dehydration method include a method using a centrifugal separator and a method of removing water by suction on a porous belt or a filtration membrane.

The methacrylic resin in a water-containing state obtained through the above dehydration can be recovered by performing a drying treatment by a conventionally known method. Examples of drying methods include: hot air drying in which drying is performed by sending hot air into a tank from a hot air blower, a blow heater, or the like; vacuum drying in which inside of a system is depressurized and heated as necessary to perform drying; barrel drying in which water is blown off by rotating the methacrylic resin obtained in a container; spin drying using centrifugal force; and the like. These drying methods may be carried out alone or in combination of two or more.

### [Emulsion Polymerization Method]

In the emulsion polymerization method, a methacrylic resin is synthesized in an emulsion in which water, a monomer mixture, an emulsifier, a polymerization initiator, a chain transfer agent, and optionally other additives are mixed.

As the monomer mixture, a monomer mixture in which the content of methyl methacrylate is 99.5% by mass or more, or 100% by mass may be used.

Examples of the emulsifier include anionic surfactants such as alkylsulfonates, alkylbenzenesulfonates, dialkylsulfosuccinates, α-olefinsulfonates, naphthalenesulfonate-formaldehyde condensates, alkylnaphthalenesulfonates, N-methyl-N-acyltaurates, phosphate ester salts (polyoxyethylene alkyl ether phosphates, etc.), etc.; nonionic surfactants; and the like. Examples of salts described above include lithium salts, sodium salts, potassium salts, calcium salts, magnesium salts, etc. These emulsifiers may be used alone or in combination of two or more types thereof. The emulsifier used in the emulsion polymerization may remain in the final methacrylic resin.

When the pH of the emulsion deviates from neutral and becomes acidic or basic, an appropriate pH adjuster can be used in order to prevent hydrolysis of methyl methacrylate as a monomer or a structural unit derived from methyl methacrylate in a methacrylic resin to be obtained by polymerization. Examples of the pH adjuster to be used include boric acid-potassium chloride-potassium hydroxide, potassium dihydrogen phosphate-sodium hydrogen phosphate, boric acid-potassium chloride-potassium carbonate, citric acid-potassium hydrogen citrate, potassium dihydrogen phosphate-boric acid, sodium hydrogen phosphate-citric acid, etc.

Examples of the polymerization initiator and the chain transfer agent include the same polymerization initiators and chain transfer agents in the suspension polymerization method described above. The polymerization initiator may be built as a redox system where necessary.

In order to obtain a methacrylic resin having a high Mw and a small proportion of terminal double bonds, the ratio of a total molar amount of the chain transfer agent to a total molar amount of the polymerization initiator is set to 3.0 or less. The ratio of a total molar amount of the chain transfer agent to a total molar amount of the polymerization initiator may be 2.6 or less, or 2.0 or less. The lower limit of the ratio of a total molar amount of the chain transfer agent to a total molar amount of the polymerization initiator is not particularly limited but may be, for example, 0.1 or more.

A solid or powdery methacrylic resin can be obtained by subjecting latex of the methacrylic resin obtained by the emulsion polymerization to heat drying or spray drying, or by subjecting the latex to a known method such as adding a water-soluble electrolyte such as a salt or an acid to coagulate the latex, and further performing heat treatment, and then separating the resin component from the aqueous phase to perform drying. The salt is not particularly limited, but may be a divalent salt, and specifically, a calcium salt such as calcium chloride, calcium acetate, etc.; a magnesium salt such as magnesium chloride, magnesium sulfate, etc.; and the like. Among these salts, magnesium salts such as magnesium chloride, magnesium sulfate, etc. are preferable. During coagulation, additives generally added, such as an anti-aging agent, an ultraviolet absorber, etc., may be added.

Before the coagulation operation described above, the latex may be filtered through a filter, a mesh, or the like to remove fine polymerization scales. This can reduce fish eyes, foreign matters, etc. caused by the fine polymerization scales, when the methacrylic resin is formed into a molded article.

In one or more embodiments, the methacrylic resin to be obtained by the aqueous polymerization may be in the form of powder, grains, or grainy powder containing both powder and grains. With regard to primary particles constituting powder, grains, and grainy powder, the suspension polymerization is suitable for preparing primary particles having an average particle diameter of about 10 to 1,000 μm, and the emulsion polymerization is suitable for preparing primary particles having an average particle diameter of about 50 to 500 nm. The powder, the grains, and the grainy powder may contain an aggregate, which is an aggregate of primary particles.

After completion of the polymerization, the methacrylic resin may be purified as necessary. As a purification method, for example, a method in which a methacrylic resin is dissolved in a solvent and a solution obtained is added dropwise to a poor solvent to cause precipitation, a method of volatilizing and removing impurities by heating the methacrylic resin, or other methods. These methods are appropriately selected according to the application and may be combined with each other.

### <Acrylic Crosslinked Particles>

By using a resin composition containing acrylic crosslinked particles, a resin film excellent in transparency and color tone and also excellent in mechanical strength such as folding endurance can be obtained.

The acrylic crosslinked particles can be widely used as hard or soft crosslinked particles without any particular limitation and may be in a single layer or a multilayer. For the hard crosslinked particles, a methacrylic acid ester such as methyl methacrylate, a polyfunctional monomer having two or more non-conjugated double bonds, or the like can be used as a raw material, and the hard crosslinked particles may be in the form of a core-shell polymer as described later. In particular, a core-shell elastic body having a core layer made of a thermally stable rubber-like polymer and a shell layer made of a glass-like polymer is preferable.

An acrylic crosslinked particle can be formed of, for example, a multi-layer structure polymer, e.g., a graft copolymer which is a so-called core-shell polymer. The multi-layer structure polymer is a polymer (core-shell polymer) having a polymer layer (shell layer) obtained by polymerizing a monomer mixture in the presence of polymer particles (core layer).

In the acrylic crosslinked particle, the core layer may have an average particle diameter of 125 to 400 nm. When the average particle diameter of the core layer is 125 nm or more, the resin film produced can have an excellent strength. When the average particle diameter of the core layer is 400 nm or less, the resin film produced has excellent transparency, appearance, and optical properties, etc. The average particle diameter of the core layer may be 130 nm to 380 nm, or 200 nm to 260 nm. The average particle diameter of the core layer of the acrylic crosslinked particles in one or more embodiments of the present invention is calculated by measuring light scattering at a wavelength of 546 nm using a spectrophotometer, while the core layer is in a state of a polymer latex before the shell layer is polymerized.

As the acrylic crosslinked particles, those easily swellable when dissolved and dispersed in a solvent used in the dope may be used. The easiness of swelling (degree of swelling) can be measured by the method described in International Publication No. WO 2018/212227.

The acrylic crosslinked particle may have a gel fraction of 90% or less. A gel fraction refers to a mass ratio of a methyl ethyl ketone-insoluble component of acrylic crosslinked particles to a total amount of the acrylic crosslinked particles. The acrylic crosslinked particles having a gel fraction of 90% or less means that the acrylic crosslinked particles contain a considerable amount of methyl ethyl ketone soluble-component, which easily makes primary particles of the acrylic crosslinked particles loose in the dope. The gel fraction may be 87% or less, 85% or less, 83% or less, or 80% or less. The lower limit of the gel fraction is not particularly limited and may be 65% or more, 68% or more, 70% or more, or 73% or more, because if the gel fraction is too low, mechanical properties of the resin film such as folding endurance, cracking during slitting, and cracking during punching, may be poor. The gel fraction can be measured by the method described below.

In one or more embodiments, the core layer in the acrylic crosslinked particle has a hard polymer (I) containing, as structural units, 40% to 100% by mass of a methacrylic acid ester unit (a-1), 60% to 0% by mass of another monomer unit (a-2) having a double bond copolymerizable with the (a-1), and 0.01 to 10 parts by mass of a polyfunctional monomer unit per 100 parts by mass of a total amount of the (a-1) and the (a-2), and a soft polymer (II) containing, as structural units, 60% to 100% by mass of an acrylic acid ester unit (b-1), 0% to 40% by mass of another monomer unit (b-2) having a double bond copolymerizable with the (b-1), and 0.1 to 5 parts by mass of a polyfunctional monomer unit per 100 parts by mass of a total amount of the (b-1) and the (b-2); the soft polymer (II) is bonded to the hard polymer (I); the shell layer includes a hard polymer (III) containing, as structural units, 60% to 100% by mass of a methacrylic acid ester unit (c-1), 40% to 0% by mass of another monomer unit (c-2) having a double bond copolymerizable with the (c-1), and 0 to 10 parts by mass of a polyfunctional monomer unit per 100 parts by mass of a total amount of the (c-1) and the (c-2); and the hard polymer (III) is graft-bonded to the hard polymer (I) and/or the soft polymer (II).

In one or more embodiments, the acrylic crosslinked particles can be obtained by the method described in International Publication WO 2018/212227. The polymer layer formed by a polymerization stage (I) to a polymerization stage (II) corresponds to the core layer, and the polymer layer formed by a polymerization stage (III) or subsequent stages corresponds to the shell layer.

### Polymerization Stage (I)

In the polymerization stage (I), it is preferable to polymerize a monomer mixture (a) containing 40% to 100% by mass of the methacrylic acid ester (a-1) and 60% to 0% by mass of another monomer (a-2) having a double bond copolymerizable with the (a-1), as well as 0.01 to 10 parts by mass of a polyfunctional monomer and 0.1 to 4.0 parts by mass of a chain transfer agent per 100 parts by mass of the total amount of the (a-1) and the (a-2), to obtain the hard polymer (I).

The other monomer (hereinafter, also referred to as “copolymerizable monomer”) having a copolymerizable double bond may be an alkyl ester of acrylic acid whose alkyl group has 1 to 12 carbon atoms and/or an aromatic vinyl monomer.

The monomer mixture (a) may be composed of 40% to 100% by mass of a methacrylic acid ester, 0% to 35% by mass of an acrylic acid ester, 0% to 10% by mass of an aromatic vinyl monomer, and 0% to 15% by mass of another monomer having a copolymerizable double bond, or may be composed of 51% to 96.8% by mass of a methacrylic acid ester, 3.1% to 29% by mass of an acrylic acid ester, 0.1% to 10% by mass of an aromatic vinyl monomer, and 0% to 10% by mass of another monomer having a copolymerizable double bond. Within these ranges, zipping depolymerization under high temperature conditions can be suppressed to enhance thermal stability, and the acrylic crosslinked particles obtained can be blended to a methacrylic resin without impairing optical properties such as transparency and color tone of the methacrylic resin.

Examples of the methacrylic acid ester include methyl methacrylate, ethyl methacrylate, n-butyl methacrylate, isobutyl methacrylate, t-butyl methacrylate, hexyl methacrylate, cyclohexyl methacrylate, 2-ethylhexyl methacrylate, octyl methacrylate, isobornyl methacrylate, phenyl methacrylate, and benzyl methacrylate. Among them, an alkyl ester of methacrylic acid whose alkyl group has 1 to 4 carbon atoms is preferable, and examples thereof include methyl methacrylate, ethyl methacrylate, n-butyl methacrylate, isobutyl methacrylate, and t-butyl methacrylate. Although these may be used singly or in combination of two or more of them, methyl methacrylate is particularly preferable.

The other monomer having a copolymerizable double bond may be at least one selected from the group consisting of an acrylic acid ester, an aromatic vinyl-based monomer, and a copolymerizable monomer other than the (meth)acrylic acid ester and the aromatic vinyl monomer, or one or two or more monomers selected from the group consisting of an alkyl ester of acrylic acid whose alkyl group has 1 to 12 carbon atoms, an aromatic vinyl-based monomer, and a copolymerizable monomer other than the (meth)acrylic acid ester and the aromatic vinyl monomer. As the other monomer having a copolymerizable double bond, an alkyl ester of acrylic acid whose alkyl group has 1 to 12 carbon atoms and/or an aromatic vinyl monomer are/is preferable.

An amount of the polyfunctional monomer used in the polymerization stage (I) may be 0.01 to 10 parts by mass, 0.01 to 5 parts by mass, or 0.01 to 2 parts by mass per 100 parts by mass of the total amount of the (a-1) and the (a-2). When the amount of the polyfunctional monomer used is 0.01 parts by mass or more, the transparency of the resulting film is improved, and when the amount of the polyfunctional monomer used is 10 parts by mass or less, excellent mechanical properties can be imparted to the film.

As the polyfunctional monomer, any known crosslinking agent or crosslinking monomer can be used. As the crosslinking monomer, allyl methacrylate alone or a combination of allyl methacrylate and another polyfunctional monomer may be used.

In the polymerization stage (I), it is preferable to polymerize a mixture of the monomer mixture (a) and the polyfunctional monomer in the presence of a chain transfer agent to obtain a hard polymer (I).

An amount of the chain transfer agent used in the polymerization stage (I) may be 0.1 to 4.0 parts by mass with respect to 100 parts by mass of the total of the (a-1) and (a-2). The lower limit may be 0.20 parts by mass or 0.50 parts by mass. The upper limit may be 3.5 parts by mass, or 1.5 parts by mass. The chain transfer agent has a function of increasing an amount of a free monomer having a low molecular weight. Accordingly, as the amount of the chain transfer agent used increases, the degree of crosslinking of the core layer decreases, so that the core layer more easily absorbs a solvent and the degree of swelling of the acrylic crosslinked particles is improved. As a result, the primary particles of the acrylic crosslinked particles easily come loose, and turbidity is less likely to occur in the dope. On the other hand, if the chain transfer agent is excessively used, the resin film may be difficult to obtain sufficient mechanical properties such as folding endurance, cracking during slitting, and cracking during punching. However, when the chain transfer agent is used within the above ranges, it is possible to obtain acrylic crosslinked particles which are less likely to cause turbidity in the dope and can impart excellent mechanical properties to the resin film.

The chain transfer agent used in the polymerization stage (I) is not particularly limited, and any chain transfer agent known in the art may be used. The chain transfer agents may be used alone or in combination of two or more types thereof.

When the chain transfer agent contains a sulfur component, the thermal stability of the acrylic crosslinked particle is improved. Accordingly, alkyl mercaptan-based chain transfer agents and thiophenols are preferable, and alkyl mercaptan-based chain transfer agents are more preferable. Among them, n-octylmercaptan and n-dodecylmercaptan are preferable, and n-octylmercaptan is particularly preferable.

The hard polymer (I) obtained in the polymerization stage (I) in the acrylic crosslinked particles may have an alkylthio group derived from an alkyl mercaptan-based chain transfer agent, or may have a primary and/or secondary alkylthio group derived from the primary and/or secondary alkyl mercaptan-based chain transfer agent. The alkylthio group refers to a structure represented by the chemical formula RS— (R is an alkyl group), and the primary and/or secondary alkylthio group refer(s) to a structure in which R is a primary and/or secondary alkyl group.

### Polymerization Stage (II)

In the polymerization stage (II), it is preferable to polymerize a monomer mixture (b) containing 60% to 100% by mass of an acrylic acid ester (b-1) and 0% to 40% by mass of another monomer (b-2) having a double bond copolymerizable with the (b-1), as well as 0.1 to 5 parts by mass of a polyfunctional monomer and 0 to 2.0 parts by mass of a chain transfer agent per 100 parts by mass of the total amount of the (b-1) and the (b-2), to obtain a soft polymer (II).

The other monomer having a copolymerizable double bond may be at least one selected from the group consisting of a methacrylic acid ester and other monomers having a copolymerizable double bond.

As the acrylic acid ester, an alkyl ester of acrylic acid whose alkyl group has 1 to 12 carbon atoms is preferable, and examples thereof include ethyl acrylate, n-butyl acrylate, n-octyl acrylate, 2-ethylhexyl acrylate, and cyclohexyl acrylate. These acrylic acid esters may be used singly or in combination of two or more of them. As the alkyl ester of acrylic acid, n-butyl acrylate is preferable, and a combination of n-butyl acrylate and ethyl acrylate or a combination of n-butyl acrylate and 2-ethylhexyl acrylate is also preferable. In particular, the acrylic acid ester used in the polymerization stage (II) may have a content of n-butyl acrylate of 50% to 100% by mass, or 80% to 100% by mass.

Examples of the methacrylic acid ester, the other monomer having a copolymerizable double bond, the polyfunctional monomer, and the chain transfer agent used in the polymerization stage (II) include those same as those described above with respect to the polymerization stage (I). In the polymerization stage (II), the chain transfer agent may or may not be used, or may be not used.

### Polymerization Stage (III)

In the polymerization stage (III), it is preferable to polymerize a monomer mixture (c) containing 60% to 100% by mass of a methacrylic acid ester (c-1) and 40% to 0% by mass of another monomer (c-2) having a double bond copolymerizable with the (c-1), as well as 0 to 10 parts by mass of a polyfunctional monomer and 0 to 6 parts by mass of a chain transfer agent per 100 parts by mass of the total amount of the (c-1) and the (c-2), to obtain a hard polymer (III).

To lower the Tg of the hard polymer (III) formed by the polymerization stage (III), the monomer mixture (c) may contain an acrylic acid ester. An amount of the acrylic acid ester used may be 0% to 40% by mass, 10% to 40% by mass, or 20% to 30% by mass in the monomer mixture (c).

The acrylic crosslinked particle of one or more embodiments of the present invention may have a structure in which the hard polymer (III) is graft-bonded to the hard polymer (I) and/or the soft polymer (II). All the hard polymers (III) may be graft-bonded to the hard polymer (I) and/or the soft polymer (II), or while some of the hard polymers (III) may be graft-bonded to the hard polymer (I) and/or the soft polymer (II), the remainder may exist as a polymer component (free polymer) not graft-bonded to either the hard polymer (I) or the soft polymer (II). The polymer component not graft-bonded is also deemed to constitute a part of the acrylic crosslinked particles.

Examples of the methacrylic acid ester, the other monomer having a copolymerizable double bond, the polyfunctional monomer, and the chain transfer agent used in the polymerization stage (III) include those same as those described above with respect to the polymerization stage (I). In the polymerization stage (III), the chain transfer agent may or may not be used but may be not used.

### Polymerization Stage (IV)

The acrylic crosslinked particle may include a polymerization stage other than the polymerization stages (I) to (III).

In the polymerization stage (IV), it is preferable to polymerize a monomer mixture (d) containing 40% to 100% by mass of a methacrylic acid ester (d-1), 0% to 60% by mass of an acrylic acid ester (d-2), and 0% to 5% by mass of another monomer having a copolymerizable double bond (d-3), as well as 0.1 to 10 parts by mass of a polyfunctional monomer and 0 to 6 parts by mass of a chain transfer agent per 100 parts by mass of the total amount of the (d-1), the (d-2), and the (d-3), to obtain a hard polymer (IV).

To lower the Tg of the hard polymer (IV) formed by the polymerization stage (IV), the amount of the acrylic acid ester (d-2) used may be 0% to 55% by mass, 15% to 40% by mass, or 20% to 40% by mass.

Examples of the methacrylic acid ester, the acrylic acid ester, the other monomer having a copolymerizable double bond, the polyfunctional monomer, and the chain transfer agent used in the polymerization stage (IV) include those same as those described above with respect to the polymerization stages (I) to (III). In the polymerization stage (IV), the chain transfer agent may or may not be used but may be not used.

The acrylic crosslinked particles of one or more embodiments may have a structure in which the hard polymer (IV) is graft-bonded to the hard polymer (I) and/or the soft polymer (II) and/or the hard polymer (III). All the hard polymers (IV) may be graft-bonded to the hard polymer (I) and/or the soft polymer (II) and/or the hard polymer (III), or while some of the hard polymers (IV) may be graft-bonded to the hard polymer (I) and/or the soft polymer (II) and/or the hard polymer (III), the remainder may exist as a polymer component not graft-bonded to any of the hard polymer (I), the soft polymer (II), or the hard polymer (III). The polymer component not graft-bonded is also deemed to constitute a part of the acrylic crosslinked particles.

The acrylic crosslinked particle can be produced by ordinary emulsion polymerization using a known emulsifier. From the viewpoint of improving the thermal stability of the resin film, the polymerization initiator used in the polymerization for obtaining the acrylic crosslinked particle may be a polymerization initiator whose 10-hr half-life temperature is 100 °C or lower. The polymerization initiator is not particularly limited as long as its 10-hr half-life temperature is 100 °C or lower, but the 10-hr half-life temperature of the polymerization initiator may be 100 °C or lower, 80 °C or lower, or 75 °C or lower. In addition, the polymerization initiator may be a persulfate and examples thereof include potassium persulfate, sodium persulfate, and ammonium persulfate. Among these polymerization initiators, potassium persulfate is particularly preferable.

The polymerization initiator may be used in the polymerization of the polymerization stage (I), or may be used in the polymerization of the polymerization stage using a chain transfer agent. The polymerization initiator may be used for polymerization in all the polymerization stages performed to obtain the acrylic crosslinked particle.

The total amount of the polymerization initiator used may be 0.01 to 1.0 parts by mass per 100 parts by mass of the total amount of the monomer mixture constituting the acrylic crosslinked particles. When the acrylic crosslinked particle is obtained through the three polymerization stages (I) to (III), the amount of the polymerization initiator used in each of the polymerization stages (I) to (III) may be 0.01 to 1.85 parts by mass in the polymerization stage (I), 0.01 to 0.6 parts by mass in the polymerization stage (II), and 0.01 to 0.90 parts by mass in the polymerization stage (III) per 100 parts by mass of the monomer mixture used in each of the polymerization stages (I) to (III). The amount of the polymerization initiator used in the polymerization stage (I) may be more than 1% by mass and 29% by mass or less with respect to the total amount of the polymerization initiators used.

The core layer of the acrylic crosslinked particle refers to a crosslinked structure polymer obtained by performing polymerization up to the polymerization stage (II) (accordingly, the outermost layer of the core layer is the soft polymer formed by the polymerization stage (II)), and the shell layer refers to the hard polymer obtained by performing the polymerization after the polymerization stage (II).

The thus-obtained acrylic crosslinked particle latex is coagulated by spray-drying or by adding a water-soluble electrolyte such as salt or acid. Then, a solid or powdery acrylic crosslinked particle is obtained by a known method, for example, subjecting the obtained coagulum to heat treatment, then separating a resin component from the water phase, followed by appropriate washing and drying.

In the present application, the term “soft” means that the Tg of the polymer is lower than 10 °C. From the viewpoint of enhancing the effect of improving impact resistance such as cracking resistance, the Tg of the soft polymer may be lower than 0 °C or lower than −20 °C. The term “hard” means that the Tg of the polymer is 10 °C or higher.

The hard polymer which constitutes the shell layer (when the shell layer includes multiple layers, a layer having the highest Tg among the multilayers) of the acrylic crosslinked particle may have a Tg of 10 °C or higher and 92 °C or lower. By setting the Tg of the hard polymer to 92 °C or lower, the bond strength between polymer molecular chains in the shell layer is weakened, cohesion among the primary particles of the acrylic crosslinked particles is reduced, and the primary particles of the acrylic crosslinked particles easily come loose, so that turbidity is less likely to occur in the dope.

As the Tg of the “soft” and “hard” polymers, values calculated by Fox equation using values described in Polymer Handbook (J. Brandrup, Interscience 1989) are used (for example, the Tg of polymethyl methacrylate is 105 °C and that of polybutyl acrylate is −54 °C).

According to one or more embodiments, the polymer (I) obtained in the polymerization stage (I) is a hard polymer, the polymer (II) obtained in the polymerization stage (II) is a soft polymer, and the polymer (III) obtained in the polymerization stage (III) is a hard polymer. The polymer (IV) obtained in the polymerization stage (IV) is a hard polymer. The acrylic crosslinked particle having such a configuration has a good balance of appearance, transparency, weather resistance, gloss, processability, thermal stability and the like, when blended with various methacrylic resins. Consequently, it is possible to provide a film excellent in thermal stability, weather resistance, gloss, processability, and the like without impairing characteristics to blended methacrylic resins, such as excellent color tone, appearance, and transparency.

### <Resin Composition>

The resin composition according to one or more embodiments includes the methacrylic resin according to the embodiment described above and acrylic crosslinked particles. In the resin composition according to one or more embodiments, the blending ratio of the methacrylic resin and the acrylic crosslinked particles varies depending on the use of the molded article or the like, but the mass ratio of the methacrylic resin to the acrylic crosslinked particles may be 99.9:0.1 to 65:35, or 99:1 to 65:35. When the acrylic crosslinked particles are core-shell particles, the mass ratio of the methacrylic resin to the acrylic crosslinked particles may be 95:5 to 65:35, and the mass ratio of the methacrylic resin to the acrylic crosslinked particles may be 90:10 to 60:40. When the blending amount of the methacrylic resin is 65 parts by mass or more with respect to 100 parts by mass of the total blending amount of both components, i.e., the methacrylic resin and the acrylic crosslinked particles, the properties of the methacrylic resin can be sufficiently exhibited, and when the blending amount is 95 parts by mass or less, the mechanical strength of the methacrylic resin can be sufficiently improved.

The resin composition according to one or more embodiments may further contain known additives such as a light stabilizer, an ultraviolet absorber, a heat stabilizer, a matting agent, a light diffusing agent, a coloring agent, a dye, a pigment, an antistatic agent, a thermal radiation reflecting material, a lubricant, a plasticizer, a stabilizer, a flame retardant, a mold release agent, a polymer processing aid, an antioxidant, a filler, etc. and a resin other than the methacrylic resin. Examples of the resin other than the methacrylic resin include styrene-based resins such as an acrylonitrile styrene resin, a styrene maleic anhydride resin, etc.; a polycarbonate resin; a polyvinyl acetal resin; a cellulose acylate resin; a fluororesin such as polyvinylidene fluoride, a polyfluoroalkyl (meth)acrylate resin, etc.; a silicone-based resin; a polyolefin-based resin; a polyethylene terephthalate resin; a polybutylene terephthalate resin; and the like.

In addition, in order to adjust orientation birefringence of the molded article, the resin composition according to one or more embodiments may include inorganic fine particles having birefringence described in Japanese Patent No. 3648201, Japanese Patent No. 4336586, or the like, and/or a low molecular weight compound having a molecular weight of 5,000 or less (or 1,000 or less) having birefringence described in Japanese Patent No. 3696649.

A form of the resin composition according to one or more embodiments is not particularly limited, and the resin composition may be in the form of powder, may be in the form of grains, may be in the form of grainy powder containing both powder and grains, or may be in the form of pellets.

### <Dope>

A dope used for producing a resin film by a solution casting method contains the resin composition according to one or more embodiments described above and a solvent. The solvent may include a first solvent having a hydrogen bond term δH of 1 to 12 in Hansen solubility parameters and a second solvent having a hydrogen bond term δH of 14 to 24. The dope according to one or more embodiments may further contain another component such as multilayer structure polymer particles, etc. similarly to the resin composition according to one or more embodiments described above. The components such as the methacrylic resin and the multilayer structure polymer particles are dissolved or dispersed in the solvent.

As the first solvent having a hydrogen bond term δH of 1 to 12, solvents disclosed in, for example, International Publication WO 2018/212227 can be used. These first solvents may be used alone or in combination of two or more types thereof. Among these first solvents, methyl ethyl ketone (5.1), chloroform (5.7), and methylene chloride (7.1) are preferable, and methylene chloride is more preferable from the viewpoint of excellent solubility of the methacrylic resin and high volatilization rate. The numbers in parentheses indicate the value of the hydrogen bonding term δH.

Examples of the second solvent having a hydrogen bond term δH of 14 to 24 include methanol (22.3), ethanol (19.4), isopropanol (16.4), butanol (15.8), ethylene glycol monoethyl ether (14.3), etc. The numbers in parentheses indicate the value of the hydrogen bonding term δH. These second solvents may be used alone or in combination of two or more types thereof. Among these second solvents, methanol and ethanol are preferable, and ethanol is more preferable.

A proportion of the first solvent contained in the solvent may be 55% to 95% by mass, 60% to 95% by mass, or 70% to 95% by mass.

A content of the methacrylic resin in the dope is not particularly limited and is appropriately determined in consideration of solubility of the methacrylic resin in the solvent used and/or conditions for carrying out the solution casting method, and the like. The content of the methacrylic resin may be 5% to 50% by mass, 10% to 45% by mass, or 15% to 40% by mass.

The viscosity of the dope can be appropriately adjusted by adjusting the content of the methacrylic resin and other components in the dope. From the viewpoints of coatability, filtration accuracy, and the like, the viscosity of the dope may be 1,000 poise (=100 Pa-s) or less, 500 poise (=50 Pa-s) or less, or 300 poise (=30 Pa-s) or less. The viscosity of the dope is measured by the method described in the Examples below.

The dope is used for producing a resin film by the solution casting method. When producing a resin film by the solution casting method, first, the dope according to one or more embodiments is cast on the surface of a support and is applied to form a uniform film by an applicator to form a dope film. Alternatively, a pressure die may be used to cast the dope onto a support. Then, the formed dope film is heated on the support to evaporate the solvent, thereby forming a resin film. Conditions for evaporating the solvent can be appropriately determined according to the boiling point of the solvent used. Then, the formed resin film is peeled off from the surface of the support. Note that the resin film obtained may be appropriately subjected to a drying step, a heating step, a stretching step, or the like.

### <Resin Film>

The resin film according to one or more embodiments includes the resin composition according to one or more embodiments described above. The resin film according to one or more embodiments is produced by the solution casting method, using, for example, the dope according to one or more embodiments described above.

The thickness of the resin film according to one or more embodiments may be, for example, 500 μm or less, 300 μm or less, or 200 μm or less. The thickness of the resin film according to one or more embodiments may be, for example, 10 μm or more, 30 μm or more, 50 μm or more, or 60 μm or more. The resin film having a thickness within the above range is advantageous in that the resin film is less likely to deform when vacuum molding is performed using the resin film, and breakage is less likely to occur in a deep drawn portion. Further, the resin film is also advantageous in that a resin film having uniform optical properties and excellent transparency can be manufactured.

A total light transmittance of the resin film according to one or more embodiments may be 85% or more, 88% or more, or 91% or more. When the total light transmittance is in the above range, transparency is high, and thus the film can be suitably used for optical applications requiring light transmissivity.

A Tg of the resin film according to one or more embodiments may be 120 °C or higher, 122 °C or higher, or 124 °C or higher. When the Tg is within the above ranges, the heat resistance of the resin film is sufficient.

A 5% weight loss temperature of the resin film according to one or more embodiments may be 300 °C or higher, or 305 °C or higher. Thereby, the resin film according to one or more embodiments has excellent thermal stability.

Haze of the resin film according to one or more embodiments may be 2.0% or less, 1.5% or less, 1.3% or less, or 1.0% or less. Internal haze of the resin film may be 1.5% or less, 1.0% or less, 0.5% or less, or 0.4% or less. When the haze and the internal haze are within the above ranges, transparency is high, and thus the film can be suitably used for optical applications requiring light transmissivity. Note that the haze is composed of haze inside a film and haze on a film surface (external), each haze being denoted as internal haze and external haze, respectively.

A value b* of the resin film according to one or more embodiments may be 0.3 or less, 0.25 or less, or 0.20 or less.

YI (Yellow Index) of the resin film according to one or more embodiments may be 1.2 or less, 1.0 or less, or 0.5 or less. When YI is in the above range, transparency is high, and therefore, the composition can be suitably used for optical applications requiring light transmissivity.

The resin film according to one or more embodiments may have excellent mechanical properties, for example, high folding endurance. As a method of evaluating folding endurance, an MIT folding endurance test and/or a clamshell-type folding test are/is known. With the resin film according to one or more embodiments, for example, a fold number in the MIT folding endurance test may be 2,500 times or more, or 3,000 times or more. When the fold number is within the above ranges, the folding endurance of the resin film is sufficient. Note that the fold number in the MIT folding endurance test is measured by a method described in the Examples below.

The resin film according to one or more embodiments can be suitably used as an optical film such as a polarizer protective film, etc. When the resin film according to one or more embodiments is used as the polarizer protective film, optical anisotropy may be small. In particular, not only the optical anisotropy in the in-plane direction (length direction or width direction) of the resin film but also optical anisotropy in the thickness direction may be small. That is, absolute values of in-plane retardation and thickness direction retardation may be both small. For example, when a measurement wavelength is 590 nm, an absolute value of the in-plane retardation may be 20 nm or less, or 15 nm or less. An absolute value of the thickness direction retardation may be 50 nm or less, 20 nm or less, or 15 nm or less.

The retardation is an index value calculated based on birefringence. The in-plane retardation (Re) and the thickness direction retardation (Rth) can be calculated by the respective equations below. In an ideal resin film that is perfectly optically isotropic in the three-dimensional direction, both the in-plane retardation Re and the thickness direction retardation Rth are 0.

Re=(nx−ny)×d

Rth=[(nx+ny)/2−nz]×d

In the above formula, nx, ny, and nz represent refractive indexes in respective axial directions, provided that an in-plane stretching direction (orientation direction of the polymer chain) is defined as X axis, a direction perpendicular to the X axis is defined as Y axis, and a thickness direction of the resin film is defined as Z axis. In addition, d represents the thickness of the resin film, and nx-ny represents orientation birefringence. A MD direction of the film is defined as the X-axis, but in the case of a stretched film, the stretching direction is defined as the X-axis.

In the resin film according to one or more embodiments, the value of orientation birefringence may be −5.0×10⁻⁴ to 5.0×10⁻⁴, −4.0×10⁻⁴ to 4.0×10⁻⁴, or −3.8×10⁻⁴ to 3.8×10⁻⁴. When the orientation birefringence is in the above range, there is a tendency that stable optical characteristics can be obtained without causing birefringence during molding.

### (Stretching)

The resin film according to one or more embodiments may be further stretched. By stretching the resin film, it is possible to improve mechanical strength and film thickness accuracy of the resin film.

When the resin film according to one or more embodiments is stretched, a resin film in an unstretched state is once molded from the dope according to one or more embodiments, and then uniaxial stretching or biaxial stretching is performed. Alternatively, during the molding of the resin film, a stretching operation is appropriately performed along with the progress of the steps of film formation and degassing of the solvent. Thereby, a stretched film (uniaxially stretched film or biaxially stretched film) can be produced. Stretching during film molding and stretching after film molding may be appropriately combined.

A stretching ratio of the stretched film is not particularly limited, and is appropriately determined according to the mechanical strength, surface properties, thickness accuracy, and the like of the stretched film to be produced. Although it also depends on the stretching temperature, the stretching ratio may be generally selected in the range of 1.1 to 5 times, in the range of 1.3 to 4 times, or in the range of 1.5 to 3 times. Within the stretching ratio in the range described above, mechanical properties of the film such as elongation, tear propagation strength, and flex fatigue resistance of the film tend to be significantly improved.

### (Applications)

The resin film according to one or more embodiments can be used for various applications such as transportation equipment, solar cell members, civil engineering building members, daily goods, electric and electronic devices, optical members, and medical products. In particular, since the resin film according to one or more embodiments has excellent heat resistance and optical properties, it can be suitably used for optical applications. Examples of the optical applications include a front plate (cover window) of various display devices, a diffusion plate, a polarizer protective film, a polarizing plate protective film, a retardation film, a light diffusion film, and an optical isotropic film.

Among these, the resin film according to one or more embodiments can be suitably used as a polarizer protective film or a front plate (cover window) of a display device. When the resin film according to one or more embodiments is used as a front plate (cover window) of various display devices, a functional coating layer such as a primer layer or a hard coat layer may be formed on at least one main surface of the resin film as necessary. When the resin film according to one or more embodiments is used as a polarizer protective film, the resin film according to one or more embodiments is bonded to a polarizer to form a polarizing plate. The polarizer is not particularly limited, and any conventionally known polarizer can be used. The polarizing plate is used, for example, in a display device such as a liquid crystal display device, an organic EL display device, etc.

### EXAMPLES

Hereinafter, one or more embodiments of the present invention will be described more specifically based on Examples and Comparative Examples, but the present invention is not limited to the following Examples. The measurement methods of various physical properties described in the Examples and the Comparative Examples are as follows.

### (1) Polymerization Conversion Ratio (Conversion Ratio)

A polymerization conversion ratio was determined by a weight method from a ratio of a weight of a solid content remaining after drying to a weight of the monomer charged. The weight of a solid content was determined by drying resin beads in an oven heated to 150 °C for 30 minutes.

Conversion ratio (%)=(solid content weight/charged monomer weight)×100

### (2) Average Particle Diameter of Acrylic Crosslinked Particles

An average particle diameter was measured in the state of latex. The average particle diameter was determined using light scattering at a wavelength of 546 nm, with U-5100 type ratio beam spectrophotometer manufactured by Hitachi High-Technologies as a measurement apparatus.

### (3) Gel Fraction of Acrylic Crosslinked Particles

After dissolving 1 g of acrylic crosslinked particles in 40 mL of methyl ethyl ketone, centrifugation was performed to separate them into a polymer component (gel polymer) insoluble in methyl ethyl ketone and a component soluble in methyl ethyl ketone. The obtained gel polymer was dried at 60 °C and 5 torr for 10 hours to recover the dried gel polymer. The component soluble in methyl ethyl ketone was added to 200 mL of methanol to reprecipitate and separate a methanol insoluble component (free polymer) from a methanol soluble component. The polymer was dried under the same conditions as described above, and the dried free polymer and the dried methanol-soluble fraction were recovered. The gel fraction (%) was calculated from the weight of the dried gel polymer, the weight of the dried free polymer, and the weight of the dried methanol-soluble fraction, using the following formula.

(Gel fraction)=(weight of dried gel polymer)/(weight of dried gel polymer+weight of dried free polymer+weight of dried methanol soluble fraction)×100

(4) rr

A ¹H-NMR spectrum of a methacrylic resin was measured in a deuterated chloroform solution at 22 °C for 16 integrations using a nuclear magnetic resonance apparatus (AVANCE III 400 MHz manufactured by Bruker). From the spectrum, an area (X) of a region of 0.60 ppm to 0.95 ppm and an area (Y) of a region of 0.60 ppm to 1.25 ppm were measured, assuming that tetramethylsilane (TMS) was assigned as 0 ppm. Then, rr was calculated, using the formula: (X/Y)×100.

### (5) Average Molecular Weight, Molecular Weight Distribution

With regard to a methacrylic resin, an Mw, an Mn, and a ratio (Mw/Mn) of the Mw and the Mn were calculated by a standard polystyrene conversion method using gel permeation chromatography (GPC). Specifically, analysis was carried out on the following apparatus under the following conditions, using a sample solution prepared by dissolving 40 mg of a
methacrylic resin in 2 mL of chloroform.
Measuring device: HLC-8220 GPC(Tosoh)
Detector: RI detector
Solvent: chloroform
Guard column: KF-G 4A (manufactured by Resonac)
Analysis column: KF-806M and KF-806L manufactured by Resonac were connected in series and used.
Measurement temperature: 40 °C
Eluent flow rate: 1 mL/min
Standard material: standard polystyrene (Tosoh)

### (6) Proportion of Terminal Double Bonds

As a pretreatment, a methacrylic resin was dissolved in methylene chloride, and the solution was added dropwise to methanol to precipitate and purify the resin. The precipitated resin was collected by suction filtration and dried for analysis. 20 mg of the dried methacrylic resin was dissolved in 0.6 to 0.7 mL of deuterated chloroform to prepare a solution and ¹H-NMR was measured using a nuclear magnetic resonance apparatus (AVANCE NEO 700 MHz, manufactured by Bruker). The measurement temperature and the number of scans were set to 20 °C and 8,192, respectively. The measurement was performed while erasing methoxy group-derived peaks (3.60 ppm, which is a value when the chemical shift of the solvent was assumed to be 7.26 ppm) of the methacrylic resin by using Excitation Sculpting (ES) method, which is a type of solvent erasing methods. From the obtained ¹H-NMR spectrum, a total area (X) of peaks (5.47 ppm to 5.53 ppm and 6.21 ppm) derived from the terminal double bond portion of the methacrylic resin and an area (Y) of peaks (0.5 ppm to 1.25 ppm) derived from the α-methyl group of the methacrylic resin were determined, and then the proportion of the terminal double bonds of the methacrylic resin was calculated by the formula: [(3×X)/(2×Y)×100.

### (7) Chain Transfer Agent Residual Proportion

A chain transfer agent residual proportion in a methacrylic resin was quantified using a gas chromatograph (7890 B, manufactured by Agilent Technologies). As an analysis column, DB-1 (film thickness 0.8 μm×inner diameter 0.20 mm×length 30 m manufactured by Agilent Technologies) was used, and the inlet temperature and the detector temperature were set to 150 °C and 320 °C, respectively. The analysis was performed under the conditions of heating from 35 °C to 210 °C at a ramp rate of 30 °C/min, then heating from 210 °C to 260 °C at a ramp rate of 10 °C/min, then heating from 260 °C to 320 °C at a ramp rate of 20 °C/min, and holding for 3 minutes. A calibration curve was prepared according to an internal reference method using dichloromethane as a measurement solvent and chlorobenzene as an internal reference substance, and the chain transfer agent residual proportion in the methacrylic resin was calculated.

### (8) Dope Viscosity

A methacrylic resin was dissolved in a mixed solvent composed of 93% by mass of methylene chloride and 7% by mass of ethanol to prepare a dope having a solid concentration (SC) of 10% by mass (Examples 1 and 2), 12% by mass (Example 3), or 25% by mass (Comparative Examples 1 and 2). The dope viscosity was measured using a B-type viscometer (BM II manufactured by Toki Sangyo). The temperature of the measurement sample was adjusted to 23 °C and No. 2 rotor was used. A value indicated at 30 rpm (12 rpm in Examples 1 and 3) was read.

### (9) Tg

A Tg of a resin film was measured by the following method. As a pretreatment, heat treatment was performed using a thermogravimetric analyzer (STA 7200, manufactured by Hitachi High-Tech Science) for the purpose of removing residual monomers and/or decomposition products of the polymerization initiator in the methacrylic resin. Specifically, the heat treatment was carried out under the conditions of heating from 40 °C to 190 °C at a ramp rate of 10 °C/min under a nitrogen gas flow of 200 mL/min and holding the temperature at 190 °C for 2.0 to 2.5 minutes. The Tg of the methacrylic resin after the heat treatment was measured using a differential scanning calorimeter (DSC; DSC 7000X manufactured by Hitachi High-Tech Science). First, DSC measurements were carried out under the following conditions of performing a first heating from 40 °C to 160 °C at a ramp rate of 10 °C/min under a nitrogen flow rate of 40 mL/min, cooling to 40 °C, and then performing a second heating from 40 °C to 160 °C at a ramp rate of 10 °C/min. Then, midpoint glass transition temperature was read from the DSC curve measured during the second heating (the midpoint glass transition temperature is a temperature of a point at which a straight line equidistant in the vertical axis direction from both a straight line obtained by extrapolating the baseline before the inflection point to the high temperature side and a straight line obtained by extrapolating the baseline after the inflection point to the low temperature side intersects the curve of the stepwise change portion of the glass transition).

### (10) 5% Weight Loss Temperature (Td5)

5% weight loss temperatures (Td5) of a resin film and a powder of acrylic crosslinked particles were measured using a thermogravimetric analyzer (STA 7200 manufactured by Hitachi High-Tech Science). First, a first heating was carried out from 40 °C to 190 °C at a ramp rate of 10 °C/min under a nitrogen flow rate of 200 mL/min, subsequently, the temperature was lowered to 40 °C, and then a second heating was carried out from 40 °C to 500 °C at a ramp rate of 10 °C/min. The temperature at which the weight of the sample was reduced to 95% as determined from a thermogravimetric (TG) curve measured during the second heating was defined as a 5% weight loss temperature (Td5).

### (11) Residence Heat Stability

Residence heat stability of a resin film was evaluated using a thermogravimetric analyzer (STA 7200 manufactured by Hitachi High-Tech Science). First, a heat treatment was carried out under the conditions of heating from 40 °C to 190 °C at a ramp rate of 10 °C/min under a nitrogen flow rate of 200 mL/min and holding the temperature at 190 °C for 2.0 to 2.5 minutes. Then, the mass change was recorded under the conditions of cooling to 40 °C, then heating from 40 °C to 280 °C at a ramp rate of 10 °C/min, and then holding the temperature at 280 °C for 30 minutes. The residence heat stability was evaluated from a mass reduction rate calculated by the following formula: [(X₀−X₁₅)/X₀]×100, where X₀ is a mass when the sample temperature reaches 280 °C and X₁₅ is a mass when the sample is being held at 280 °C for 15 minutes.

### (12) Total Light Transmittance

A total light transmittance of a stretched resin film was measured using a haze meter (manufactured by Suga Test Instruments, HZ-V3) in accordance with JIS K7361-1.

### (13) Internal Haze

Haze of the stretched resin film was measured using a haze meter (HZ-V3 manufactured by Suga Test Instruments) in accordance with JIS K7136. Further, both surfaces of the resin film were sandwiched by glycerin and glass in this order. The result obtained was converted to a film thickness equivalent to 40 μm.

### (14) YI

YI of a stretched resin film was measured using a spectrophotometer (SC-P manufactured by Suga Test Instruments) in accordance with JIS K7373. The result obtained was converted to a film thickness equivalent to 40 μm.

### (15) Value b*

Value b* of a stretched resin film was measured using a spectrophotometer (SC-P manufactured by Suga Test Instruments) in accordance with JIS Z8781-4.

### (16) MIT Folding Endurance Test

A stretched resin film was cut into strips having a width of 15 mm and the strips were used as test pieces. One of these test pieces was set in an MIT anti-flex fatigue tester model D manufactured by Toyo Seiki in a direction in which a crease was formed perpendicularly to the stretching direction. A fold number of reciprocal folding when the test piece was broken was determined by the measurement under the conditions of a test load of 1.96 N, a speed of 175 times/minute, the radius of curvature R of the folding clamp of 0.38 mm, and the folding angle to the left and right of 135°. The measurement was carried out five times and the arithmetic average value was taken as the fold number of MIT reciprocating folding.

### <Production of Methacrylic Resin (Resin A)>

A 5-liter glass reactor equipped with an H-type stirring blade type stirrer was charged with 150 parts by mass of deionized water, 0.40 parts by mass of calcium triphosphate as a dispersant, 0.0075 parts by mass of sodium α-olefin sulfonate, and 0.30 parts by mass of sodium chloride. While stirring at 250 rpm under a nitrogen atmosphere, the reactor was charged with 100 parts by mass of methyl methacrylate (MuA), 0.02 parts by mass of n-octylmercaptan (n-OM) as a chain transfer agent, and 0.012 parts by mass of 2,2′-azobis(isobutyrate)dimethyl (V-601, manufactured by Fujifilm Wako Pure Chemical) as a polymerization initiator. Thereafter, the temperature of the liquid in the reactor was raised to 75 °C to start polymerization. 2 hours after the start of polymerization, 0.10 parts by mass of calcium triphosphate were added to the reaction solution. 4 hours and 35 minutes after the start of polymerization, an exothermic peak resulting from the gel effect was observed. 5 hours and 30 minutes after the start of polymerization, the temperature of the liquid in the reactor was raised to 95 °C. 5 hours and 30 minutes after the start of polymerization, the conversion ratio was 94%. 3 hours after the temperature reached 95 °C, the reactor was cooled to room temperature to terminate the polymerization. The conversion ratio at the end of polymerization was 99%. The methacrylic resin bead dispersion obtained by the above polymerization was acid-washed using 1 N hydrochloric acid solution in an amount of 0.1 times the amount of the charged monomer in mass ratio and washed with water to remove the dispersant and the like, further followed by dehydration and drying to obtain a bead-like methacrylic resin (resin A).

### <Production of Acrylic Crosslinked Particles (1)>

An 8-liter polymerization apparatus equipped with a stirrer was charged with 175 parts by mass of deionized water, 0.01 parts by mass of polyoxyethylene lauryl ether phosphoric acid, 0.5 parts by mass of boric acid, and 0.05 parts by mass of sodium carbonate. After the interior of the polymerization apparatus was sufficiently replaced with nitrogen gas, the internal temperature was adjusted to 80 °C, and 26% of (I) shown in Table 1 was added to the polymerization apparatus at one time. Then, 0.06 parts by mass of sodium formaldehyde sulfoxylate, 0.006 parts by mass of ethylenediaminetetraacetic acid disodium, 0.001 parts by mass of ferrous sulfate, and 0.02 parts by mass of t-butyl hydroperoxide were added. 15 minutes thereafter, 0.03 parts by mass of t-butyl hydroperoxide were added and polymerization was further continued for 15 minutes. Next, 0.01 parts by mass of sodium hydroxide were added as a 2% aqueous solution, 0.09 parts by mass of polyoxyethylene lauryl ether phosphoric acid were added, and remaining 74% of (I) was continuously added over 60 minutes. 30 minutes after the completion of the addition, 0.07 parts by mass of t-butyl hydroperoxide were added and the polymerization was further continued for 30 minutes to obtain a polymer (I). Thereafter, 0.03 parts by mass of sodium hydroxide in a 2% aqueous solution and 0.08 parts by mass of potassium persulfate in a 2% aqueous solution were added, and then (II) shown in Table 1 was continuously added over 150 minutes. After the completion of the addition, 0.02 parts by mass of potassium persulfate in a 2% aqueous solution were added and polymerization was continued for 120 minutes to obtain a polymer (II). The average particle diameter was 225 nm. Thereafter, 0.02 parts by mass of potassium persulfate in a 2% aqueous solution were added, (III-1) shown in Table 1 was continuously added over 45 minutes, and polymerization was continued for an additional 30 min. Thereafter, (III-2) shown in Table 1 was continuously added over 25 minutes, and polymerization was further continued for 60 minutes to obtain a latex of acrylic crosslinked particles (1). The obtained latex was salted out with magnesium chloride, coagulated, washed with water, and dried to obtain acrylic crosslinked particles (1) in the form of white powder. The acrylic crosslinked particles (1) had a Td5 of 294 °C and a gel fraction of 93.7%.

### <Production of Acrylic Crosslinked Particles (2)>

An 8-liter polymerization apparatus equipped with a stirrer was charged with 180 parts by mass of deionized water, 0.003 parts by mass of polyoxyethylene lauryl ether phosphoric acid, 0.5 parts by mass of boric acid, 0.05 parts by mass of sodium carbonate, and 0.01 parts by mass of sodium hydroxide. After the interior of the polymerization apparatus was sufficiently replaced with nitrogen gas, the internal temperature was adjusted to 80 °C, 0.03 parts by mass of potassium persulfate were added as a 2% aqueous solution, and then (I) shown in Table 1 was continuously added over 81 minutes. The polymerization was continued for an additional 60 minutes to obtain a polymer (I). Thereafter, 0.03 parts by mass of sodium hydroxide were added as a 2% aqueous solution, 0.08 parts by mass of potassium persulfate were added as a 2% aqueous solution, and then (II) shown in Table 1 was continuously added over 150 minutes. After the completion of the addition, 0.02 parts by mass of pure potassium persulfate were added as a 2% aqueous solution, and polymerization was continued for 120 minutes to obtain a polymer (II). The average particle diameter was 224 nm. Thereafter, 0.02 parts by mass of potassium persulfate were added as a 2% aqueous solution, (III) shown in Table 1 was continuously added over 70 minutes, and polymerization was further continued for 60 minutes to obtain a latex of acrylic crosslinked particles (2). The obtained latex was salted out with magnesium chloride, coagulated, washed with water, and dried to obtain acrylic crosslinked particles (2) in the form of white powder. The acrylic crosslinked particles (2) had a Td5 of 338 °C and a gel fraction of 79.0%.

TABLE 1

| | | | Crosslinked | Crosslinked |
|---|---|---|---|---|
| | | | particles | particles |
| | | | (1) | (2) |
| Polymerization | | Monomer mixture (a) in part(s) per 100 parts of | 27 | 27 |
| stage (I) | | total monomers for crosslinked particles | | |
| | | Methyl methacrylate (%) | 97 | 93.2 |
| | | Butyl acrylate (%) | 3 | 6 |
| | | Styrene (%) | 0 | 0.8 |
| | | Allyl methacrylate in part(s) per 100 parts of | 0.135 | 0.135 |
| | | total monomers for crosslinked particles | | |
| | | n-OM in part(s) per 100 parts of total monomers for | 0 | 0.3 |
| | | crosslinked particles | | |
| | | t-DM in part(s) per 100 parts of total monomers for | 0.1 | 0 |
| | | crosslinked particles | | |
| | | Emulsifier in part(s) per 100 parts of total | 0.09 | 0.09 |
| | | monomers for crosslinked particles | | |
| Polymerization | | Monomer mixture (b) in part(s) per 100 parts of | 50 | 50 |
| stage (II) | | total monomers for crosslinked particles | | |
| | | Butyl acrylate (%) | 82 | 82 |
| | | Styrene (%) | 18 | 18 |
| | | Allyl methacrylate in part(s) per 100 parts of | 0.75 | 0.75 |
| | | total monomers for crosslinked particles | | |
| | | Emulsifier in part(s) per 100 parts of total | 0.2 | 0.2 |
| | | monomers for crosslinked particles | | |
| Average particle diameter at the end of polymerization stage (II) (nm) | | | 225 | 224 |
| Polymerization | (III-1) | Monomer mixture (c) in part(s) per 100 parts of | 15 | 23 |
| stage (III) | | total monomers for crosslinked particles | | |
| | | Methyl methacrylate (%) | 95 | 80 |
| | | Butyl acrylate (%) | 5 | 20 |
| | (III-2) | Monomer mixture (d) in part(s) per 100 parts of | 8 | 0 |
| | | total monomers for crosslinked particles | | |
| | | Methyl methacrylate (%) | 52 | 0 |
| | | Butyl acrylate (%) | 48 | 0 |

93% by mass of methylene chloride was placed in a screw tube container, and 10 parts by mass of a powder of acrylic crosslinked particles (1) were added little by little while stirring with a magnetic stirrer. The resulting dispersion of acrylic crosslinked particles was subjected to dispersion treatment at 8,000 rpm for 10 minutes using a homogenizer (Ultra-Turrax T 25, manufactured by Ika) and then 7% by mass of ethanol was added to the dispersion. Thereafter, 90 parts by mass of a methacrylic resin (resin A) were added little by little while stirring and the mixture was stirred until completely dissolved to prepare a resin dope having a solid content concentration of 12%. The above-mentioned dope was cast on a glass substrate and applied to form a uniform film by an applicator. At this time, the clearance was adjusted so that the thickness after drying was about 80 μm. After the application, the doped film was dried in an oven at 40 °C for 1 hour, and then the obtained resin film was peeled off from the glass substrate. The surface adhered to the glass substrate was referred to as surface B, and the other surface was referred to as surface A. Thereafter, the resin film was fixed to a stainless steel frame and dried in an oven at 140 °C for 2 hours to remove the remaining solvent, thereby obtaining a resin film. Further, the obtained resin film was subjected to width-fixed uniaxial stretching at 145 °C. A stretched resin film (stretched film) was obtained at a stretching ratio of 2. Each physical property is shown in Table 2.

### Example 2

A resin film and a stretched film were obtained in the same manner as in Example 1 except that 20 parts by mass of the acrylic crosslinked particles (1) and 80 parts by mass of the methacrylic resin (resin A) were used instead of 10 parts by mass of the acrylic crosslinked particles (1) and 90 parts by mass of the methacrylic resin (resin A) in Example 1. Each physical property is shown in Table 2.

### Example 3

A resin film and a stretched film were obtained in the same manner as in Example 1 except that 20 parts by mass of the acrylic crosslinked particles (2) and 80 parts by mass of the methacrylic resin (resin A) were used instead of 10 parts by mass of the acrylic crosslinked particles (1) and 90 parts by mass of the methacrylic resin (resin A) in Example 1. Each physical property is shown in Table 2.

### Comparative Example 1

93% by mass of methylene chloride and 7% by mass of ethanol were placed in a screw tube container, and 100 parts by mass of the methacrylic resin (resin A) were added little by little while stirring with a magnetic stirrer. The mixture was stirred until completely dissolved to prepare a resin dope having a solid content concentration of 12%. The above-mentioned dope was cast on a glass substrate and applied to form a uniform film by an applicator. At this time, the clearance was adjusted so that the thickness after drying was about 80 μm. After the application, the doped film was dried in an oven at 40 °C for 1 hour, and then the obtained resin film was peeled off from the glass substrate. Thereafter, the resin film was fixed to a stainless-steel frame and dried in an oven at 140 °C for 2 hours to remove the remaining solvent, thereby obtaining a resin film. Further, the obtained resin film was subjected to width-fixed uniaxial stretching at 145 °C. A stretched resin film (stretched film) was obtained at a stretching ratio of 2. Each physical property is shown in Table 2. As compared with Examples 1 to 3, the fold number of MIT reciprocating folding was small and thus the folding endurance was low.

### Comparative Example 2

A resin film and a stretched film were obtained in the same manner as in Comparative Example 1 except that a methacrylic resin (resin B) (Parapet HR-F manufactured by Kuraray Co., Ltd.) was used instead of the methacrylic resin (resin A) in Comparative Example 1. Each physical property is shown in Table 2. As compared with Examples 1 to 3, the Tg was low and thus the heat resistance was insufficient; and the fold number of MIT reciprocating folding was very small and thus the folding endurance was very low.

### Comparative Example 3

A resin film and a stretched film were obtained in the same manner as in Example 1 except that 20 parts by mass of the acrylic crosslinked particles (1) and 80 parts by mass of the methacrylic resin (resin B) were used instead of 10 parts by mass of the acrylic crosslinked particles (1) and 90 parts by mass of the methacrylic resin (resin A) in Example 1. Each physical property is shown in Table 2. As compared with Examples 1 to 3, the Tg was low and thus the heat resistance was insufficient; the fold number of MIT reciprocating folding was small and thus the folding endurance was low; and the total light transmittance was less than 90% and thus the transparency was also low.

### Comparative Example 4

A resin film and a stretched film were obtained in the same manner as in Example 1 except that 20 parts by mass of the acrylic crosslinked particles (1) and 80 parts by mass of a methacrylic resin (Resin C) (Parapet HR-S, manufactured by Kuraray Co., Ltd.) were used instead of 10 parts by mass of the acrylic crosslinked particles (1) and 90 parts by mass of the methacrylic resin (Resin A) in Example 1. Each physical property is shown in Table 2. As compared with Examples 1 to 3, the Tg was low and thus the heat resistance was insufficient; and the total light transmittance was less than 91% and thus the transparency was low.

TABLE 2

| | | | | | | Comparative |
|---|---|---|---|---|---|---|
| | | | Example 1 | Example 2 | Example 3 | Example 1 |
| Methacrylic | Methacrylic | Resin A (phr) | 90 | 80 | 80 | 100 |
| resin | resin | Resin B (phr) | | | | |
| composition | | Resin C (phr) | | | | |
| | Acrylic | Acrylic crosslinked | 10 | 20 | | |
| | crosslinked | particle (1) (phr) | | | | |
| | particle | Acrylic crosslinked | | | 20 | |
| | | particle (2) (phr) | | | | |

| | | |
|---|---|---|
| Methacrylic | rr (%) | 58 |
| resin | Mw | 1,119,000 |
| | Mw/Mn | 1.85 |
| | Amount of terminal | 0.002 |
| | double bonds (mol %) | |

| Resin film | Tg (°C) | 128 | 124 | 124 | 124 |
|---|---|---|---|---|---|
| | Td5 (°C) | 306 | 307 | 325 | 309 |
| | Residence heat stability (%) | 4.2 | 4.0 | 1.9 | 4.2 |
| Stretched film | Total light transmittance (%) | 92.6 | 92.5 | 92.6 | 92.5 |
| | Inner haze (%) | 0.27 | 0.35 | 0.35 | 0.28 |
| | YI | 0.32 | 0.33 | 0.45 | 0.23 |
| | b* | 0.15 | 0.16 | 0.22 | 0.11 |
| | fold number (times) of MIT | 3,082 | 10,989 | 7,069 | 2,339 |
| | reciprocating folding | | | | |

| | | | Comparative | Comparative | Comparative |
|---|---|---|---|---|---|
| | | | Example 2 | Example 3 | Example 4 |
| Methacrylic | Methacrylic | Resin A (phr) | | | |
| resin | resin | Resin B (phr) | 100 | 80 | |
| composition | | Resin C (phr) | | | 80 |
| | Acrylic | Acrylic crosslinked | | 20 | 20 |
| | crosslinked | particle (1) (phr) | | | |
| | particle | Acrylic crosslinked | | | |
| | | particle (2) (phr) | | | |

| | | | |
|---|---|---|---|
| Methacrylic | rr (%) | 56 | 51 |
| resin | Mw | 100,000 | 122,000 |
| | Mw/Mn | 1.89 | 1.89 |
| | Amount of terminal | — | 0.005 |
| | double bonds (mol %) | | |

| Resin film | Tg (°C) | 114 | 114 | 116 |
|---|---|---|---|---|
| | Td5 (°C) | 331 | 329 | 329 |
| | Residence heat stability (%) | 1.5 | 1.5 | 1.4 |
| Stretched film | Total light transmittance (%) | 92.6 | 89.7 | 90.6 |
| | Inner haze (%) | 0.16 | 0.23 | 0.30 |
| | YI | 0.13 | 0.97 | 0.37 |
| | b* | 0.06 | 0.48 | 0.18 |
| | fold number (times) of MIT | 36 | 1,048 | — |
| | reciprocating folding | | | |

Although the disclosure has been described with respect to only a limited number of embodiments, those skilled in the art, having benefit of this disclosure, will appreciate that various other embodiments may be devised without departing from the scope of the present disclosure. Accordingly, the scope of one or more embodiments of the invention should be limited only by the attached claims.

1. A resin composition comprising:
a methacrylic resin having a triad syndiotacticity of 55% or more and a weight average molecular weight (Mw) as measured by gel permeation chromatography (GPC) of 500,000 or more, and
acrylic crosslinked particles.

2. The resin composition according to claim 1, wherein a mass ratio of the methacrylic resin and the acrylic crosslinked particles is from 99.9:0.1 to 65:35 inclusive.

3. The resin composition according to claim 1, having a proportion of a structural unit derived from methyl methacrylate of 99.5% by mass or more.

4. The resin composition according to claim 1, wherein the methacrylic resin has a ratio (Mw/Mn) of the weight average molecular weight (Mw) to a number average molecular weight (Mn) of 1.6 to 2.8 inclusive.

5. The resin composition according to claim 1, having a proportion of terminal double bonds to structural units derived from methyl methacrylate of less than 0.02 mol %.

6. The resin composition according to claim 1, wherein the methacrylic resin comprises a terminal structure derived from a polymerization initiator and represented by the following formula (1): 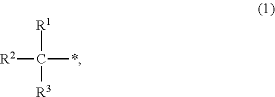
wherein R¹, R², and R³ each independently represent an alkyl group, a substituted alkyl group, an ester group, or an amide group, provided that at least one of R¹, R², or R³ represents an ester group or an amide group, two of R¹, R², or R³ may be bonded to each other to form an alicyclic structure, and * represents a bond to a structural unit derived from a monomer.

7. The resin composition according to claim 1, wherein the acrylic crosslinked particles are core-shell elastomers having a core layer composed of a rubber-like polymer, and a shell layer composed of a glass-like polymer.

8. A dope for producing a film by a solution casting method, comprising:
the resin composition according to claim 1; and
a solvent comprising:
a first solvent having a hydrogen bond term δH in a Hansen solubility parameter of 1 to 12 inclusive; and
a second solvent having a hydrogen bond term δH of 14 to 24 inclusive.

9. A resin film comprising the resin composition according to claim 1.

10. The resin film according to claim 9, having a glass transition temperature of 120 °C or higher.

11. The resin film according to claim 9, having a fold number in an MIT folding endurance test of 2,500 times or more.

12. The resin film according to claim 9, having an internal haze of 0.4% or less.

13. The resin film according to claim 9, having value b* of 0.3 or less.

14. A method for producing the resin composition according to claim 1, comprising a production method of the methacrylic resin comprising a polymerization step of polymerizing a monomer mixture having a methyl methacrylate content of 99.5% by mass or more in a presence of a polymerization initiator and a chain transfer agent,
wherein, in the polymerization step:
a polymerization temperature until 90% or more of the methacrylic resin to be obtained is produced is set to lower than 100 °C,
an amount of the chain transfer agent is 0.03 mol % or less with respect to a total amount of the monomer mixture, and
a ratio of a molar amount of the chain transfer agent to a total molar amount of the polymerization initiator is 3.0 or less.

15. The method for producing the resin composition according to claim 14, wherein the polymerization initiator in the production method of the methacrylic resin is a non-nitrile azo polymerization initiator.

16. The method for producing the resin composition according to claim 14, wherein aqueous polymerization is performed in the polymerization step in the production method of the methacrylic resin.

17. The resin film according to claim 9, wherein the resin film is an optical film.

18. The resin film according to claim 9, wherein the resin film is a polarizer protective film.

19. A polarizing plate comprising a laminate of a polarizer and the resin film according to claim 9.

20. A display device comprising the polarizing plate according to claim 19.
